(19) United States
(12) Patent Application Publication
(10) Pub. No.: US 2025/0255069 A1
(43) Pub. Date: Aug. 7, 2025

(54) ELECTRONIC DEVICE

(71) Applicant: Japan Display Inc., Tokyo (JP)

(72) Inventors: Kenichi TAKEMASA, Tokyo (JP); Kazuyuki YAMADA, Tokyo (JP); Keisuke ASADA, Tokyo (JP); Daiki ISONO, Tokyo (JP)

(21) Appl. No.: 19/042,280

(22) Filed: Jan. 31, 2025

(30) Foreign Application Priority Data
Feb. 7, 2024 (JP) 2024-017174

(51) Int. Cl. H10H 29/39; H01L 23/00; H01L 25/16

(52) U.S. Cl. CPC H10H 29/39; H01L 24/16; H01L 25/167; H01L 2224/16013; H01L 2224/16014; H01L 2224/16111; H01L 2224/16227

(57) ABSTRACT

To improve a performance of an electronic device. A substrate structure (electronic device) includes a terminal formed on a wiring layer, an insulating layer covering the wiring layer, and a bump electrode electrically connected to the terminal. The insulating layer includes an opening penetrating the insulating layer in a thickness direction. The terminal has an exposed surface exposed from the insulating layer in the opening. In plan view of the terminal viewed from above, at least one of the insulating layer, the bump electrode, and the terminal has a shape capable of identifying presence or absence the bump electrode.

### CROSS REFERENCES TO RELATED APPLICATIONS

The present application claims priority to Japanese Patent Application No. 2024-17174 filed on Feb. 7, 2024, the disclosure of which is incorporated herein by reference.

### BACKGROUND

The present disclosure relates to an electronic device.

There are electronic devices each including an electronic component mounted on a plurality of electrodes arranged on a substrate. For example, Japanese Unexamined Patent Application Publication No. 2021-15177 (Patent Document 1) describes an electronic device including a light emitting diode (LED) element mounted on a plurality of electrodes arranged on a substrate.

### SUMMARY

In the case of an electronic device including an electronic component mounted on a terminal formed on a substrate, a bump electrode is formed on the terminal of the substrate in order to facilitate connection between an electrode of the electronic component and the terminal on the substrate. From the viewpoint of improving the reliability of the electronic device, it is necessary to form the bump electrode on the terminal as designed.

An object of the present disclosure is to provide a technique of improving a performance of an electronic device.

An electronic device according to an embodiment includes a substrate including a first surface and a second surface opposite to the first surface, a wiring layer disposed on the first surface of the substrate, a terminal formed on the wiring layer, a first insulating layer covering the wiring layer, and a bump electrode electrically connected to the terminal. The first insulating layer includes a first opening penetrating the first insulating layer in a thickness direction. The terminal has an exposed surface exposed from the first insulating layer in the first opening. In plan view of the terminal viewed from above, at least one of the first insulating layer, the bump electrode, and the terminal has a shape capable of identifying presence or absence the bump electrode.

An electronic device according to another embodiment includes a substrate including a first surface and a second surface opposite to the first surface, a wiring layer disposed on the first surface of the substrate, a terminal formed on the wiring layer and made of a visible light-transmitting conductive material, a first insulating layer covering the wiring layer, and a bump electrode electrically connected to the terminal. The first insulating layer includes a first opening penetrating the first insulating layer in a thickness direction. The terminal has an exposed surface exposed from the first insulating layer in the first opening. A member between the exposed surface of the terminal and the second surface of the substrate is made of a visible-light-transmitting material.

### BRIEF DESCRIPTIONS OF THE DRAWINGS

FIG. 1 is a plan view illustrating a configuration example of a micro LED display device which is an embodiment of an electronic device.

FIG. 2 is a circuit diagram illustrating a configuration example of a circuit in periphery of a pixel illustrated in FIG. 1.

FIG. 3 is a perspective enlarged plan view illustrating an example of a peripheral structure of an LED element arranged in each of a plurality of pixels of the display device illustrated in FIG. 1.

FIG. 4 is an enlarged cross-sectional view taken along a line A-A of FIG. 3.

FIG. 5 is an enlarged plan view illustrating an upper surface of a substrate structure before mounting of the LED element illustrated in FIG. 3.

FIG. 6 is an enlarged plan view illustrating a modification example with respect to FIG. 5.

FIG. 7 is an enlarged plan view illustrating a study example relative to FIG. 6.

FIG. 8 is an enlarged cross-sectional view taken along a line A-A of FIG. 5.

FIG. 9 is an enlarged cross-sectional view taken along a line B-B of FIG. 7.

FIG. 10 is an explanatory diagram illustrating an example of a step flow of a method of manufacturing a display device according to an embodiment of the electronic device.

FIG. 11 is an enlarged cross-sectional view illustrating a state where a mask is formed on an exposed surface of a terminal in a mask forming step illustrated in FIG. 10.

FIG. 12 is an enlarged cross-sectional view illustrating a state where a bump electrode is formed in an opening formed in the mask by a plating method in a plating step illustrated in FIG. 10.

FIG. 13 is an explanatory diagram illustrating an example of an inspection device inspecting a substrate structure in a bump electrode inspecting step illustrated in FIG. 10.

FIG. 14 is an explanatory diagram illustrating an example of an image acquired by the inspection device illustrated in FIG. 13.

FIG. 15 is an enlarged plan view of a substrate structure as a modification example with respect to FIG. 5.

FIG. 16 is an enlarged cross-sectional view taken along a line C-C of FIG. 15.

FIG. 17 is an enlarged cross-sectional view of a substrate structure as a modification example with respect to FIG. 16.

FIG. 18 is an enlarged cross-sectional view of a substrate structure as another modification example relative to FIG. 16.

FIG. 19 is an enlarged plan view of a substrate structure as another modification example relative to FIG. 5.

FIG. 20 is an enlarged cross-sectional view taken along a line D-D of FIG. 19.

FIG. 21 is an explanatory diagram illustrating a modification example with respect to FIG. 13.

FIG. 22 is an enlarged plan view of a substrate structure as another modification example relative to FIG. 5.

FIG. 23 is an enlarged cross-sectional view taken along a line E-E of FIG. 22.

FIG. 24 is an enlarged cross-sectional view illustrating a modification example with respect to FIG. 23.

### DESCRIPTIONS OF THE PREFERRED EMBODIMENTS

Hereinafter, each embodiment of the present disclosure will be described with reference to the drawings. Note that disclosure is merely an example, and appropriate modification with keeping the gist of the present disclosure which can be easily anticipated by those who are skilled in the art is obviously within the scope of the present disclosure. In order to make the description clear, a width, a thickness, a shape, and others of each portion in the drawings are schematically illustrated more than those in an actual aspect in some cases; however, the illustration is merely an example, and does not limit the interpretation of the present disclosure. In the present specification and each drawing, similar elements to those described earlier for the already-described drawings are denoted with the same or similar reference characters, and detailed description for them is appropriately omitted in some cases.

In the following embodiments, as an example of an electronic device including an arranged bump electrode array used for mounting a plurality of electronic components, a micro LED display device on which a plurality of micro LED elements is mounted and a bump electrode array device before mounting a plurality of micro LED elements will be exemplified and explained.

In the present application, the expression “a member A is made of B” may be used in describing a material constituting a specific member. This means “among materials constituting the member A, a material contained in the largest amount by weight is B”. Therefore, in addition to a case where the member A does not contain impurities and is formed of only B, there is a case where the member A contains a material other than B as impurities.

### Electronic Device

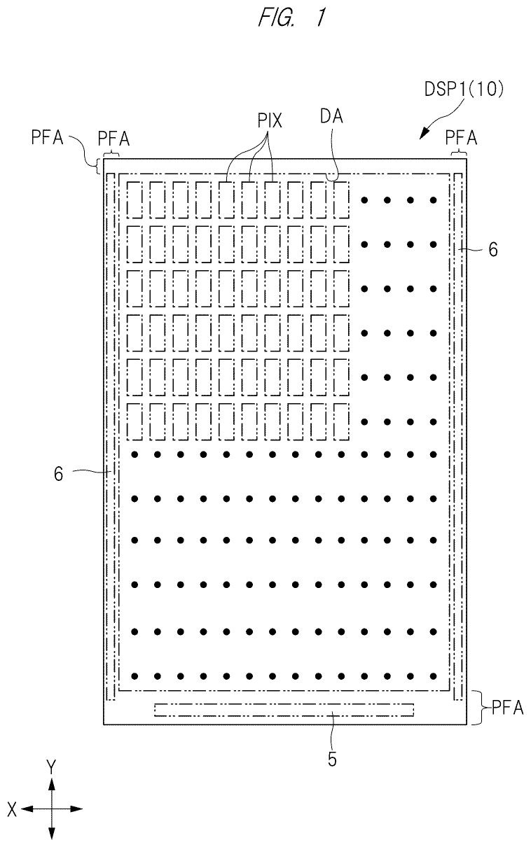

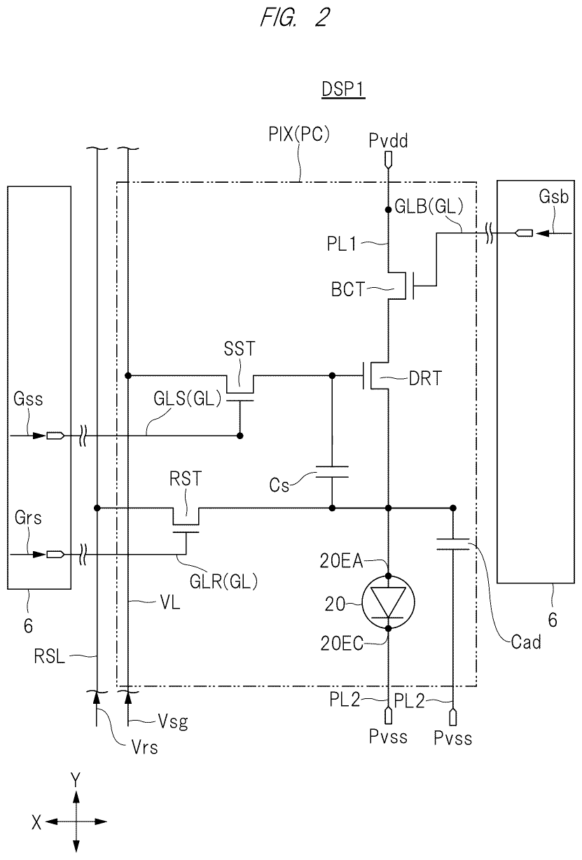

First, a configuration example of a micro LED display device which is an aspect of an electronic device of the present embodiment will be described. FIG. 1 is a plan view illustrating a configuration example of a display device which is an embodiment. In FIG. 1, a boundary between a display area DA and a peripheral area PFA, a control circuit 5, drive circuits 6, and a plurality of pixels PIX are indicated by two-dot chain lines. FIG. 2 is a circuit diagram illustrating a configuration example of a circuit in periphery of a pixel illustrated in FIG. 1. Note that a pixel circuit PC illustrated in FIG. 2 illustrates an example of an equivalent circuit corresponding to one pixel PIX illustrated in FIG. 1.

FIG. 1 illustrates an X direction and a Y direction. The X direction and the Y direction cross each other. In the example described below, the X direction is orthogonal to the Y direction. Hereinafter, an X-Y plane including the X direction and the Y direction will be described as a plane parallel to the display surface of the display device. In the following description, unless otherwise specified, “plan view” means a view of a plane parallel to the X-Y plane. As described later, the normal direction with respect to the X-Y plane will be described as a “Z direction” or a thickness direction. The X direction, the Y direction, and the Z direction are directions crossing each other, more specifically, directions orthogonal to each other.

In the description of the present specification, “A” may be described as “covered” with “B”. The expression “A is covered with B” means that at least a part of A overlaps B in plan view in which the X-Y plane is viewed. The expression “A is covered with B” can also be rephrased as “at least a part of A overlaps B in the thickness direction (Z direction)” described above.

As illustrated in FIG. 1, a display device DSP1 of the present embodiment has the display area DA, the peripheral area PFA surrounding the periphery of the display area DA in a frame shape, and the plurality of pixels PIX arranged in a matrix in the display area DA. The display device DSP1 includes a substrate 10, the control circuit 5 formed on the substrate 10, and the drive circuits 6 formed on the substrate 10.

The control circuit 5 is a control circuit controlling driving of a display function of the display device DSP1. For example, the control circuit 5 is a driver integrated circuit (IC) mounted on the substrate 10. In an example illustrated in FIG. 1, the control circuit 5 is disposed along one short side among four sides of the substrate 10. In the example of the present embodiment, the control circuit 5 includes a signal line drive circuit (video driver) driving a video signal line VL (see FIG. 2) connected to the plurality of pixels PIX. However, the position and configuration example of the control circuit 5 are not limited to the example illustrated in FIG. 1, and there are various modification examples. For example, in FIG. 1, a circuit board such as a flexible substrate may be connected to a position illustrated as the control circuit 5, and the driver IC may be mounted on the circuit board. For example, the signal line drive circuit driving the video signal line VL may be formed separately from the control circuit 5.

The drive circuit (scanning driver) 6 is a circuit driving scanning signal lines GLB, GLR, and GLS (see FIG. 2) among the plurality of pixels PIX. The drive circuit 6 drives the plurality of scanning signal lines based on a control signal from the control circuit 5. In the example illustrated in FIG. 1, the drive circuits 6 each are disposed along two long sides among the four sides of the substrate 10. In the example illustrated in FIG. 1, in plan view, the display area DA is disposed between the two drive circuits 6. However, the position and configuration example of the drive circuits 6 are not limited to the example illustrated in FIG. 1, and there are various modification examples. For example, in FIG. 1, a circuit board such as a flexible substrate may be connected to a position illustrated as the control circuit 5, and the control circuit 5 and the drive circuit 6 may be mounted on the circuit board.

Next, a configuration example of the pixel circuit PC driving the pixel PIX illustrated in FIG. 1 will be described with reference to FIG. 2. Note that, in FIG. 2, one pixel circuit PC driving one pixel is representatively taken and illustrated. Each of the plurality of pixels PIX illustrated in FIG. 1 includes a circuit similar to the pixel circuit PC illustrated in FIG. 2. The pixel circuit PC is a voltage signal type circuit controlling a light emitting state of the LED element (inorganic light emitting diode element, diode element) 20 according to a video signal Vsg supplied from the control circuit 5 (see FIG. 1).

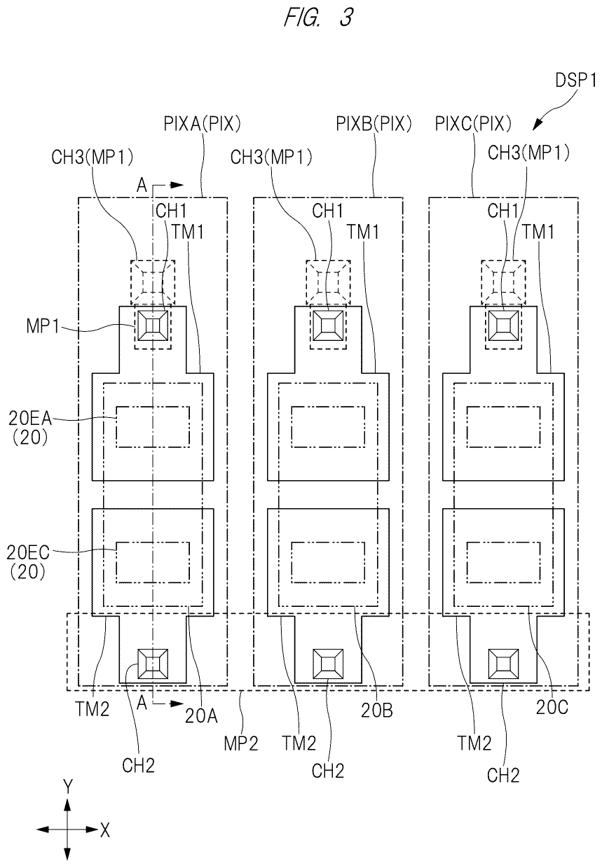

As illustrated in FIG. 2, the pixel PIX includes an LED element 20. The LED element 20 is the above-described micro light emitting diode. The LED element 20 includes an anode electrode 20EA (see FIG. 3 described later) and a cathode electrode 20EC (see FIG. 3 described later).

The display device DSP1 includes a plurality of types of wirings in the display area DA. These wirings include a plurality of scanning signal lines GLS, GLR, and GLB, a plurality of video signal lines VL, a plurality of power supply lines PL1, a plurality of power supply lines PL2, and a plurality of reset wirings RSL.

The scanning signal lines GLS, GLR, and GLB extend in an X direction and are connected to the drive circuit 6. For example, as illustrated in FIG. 1, among the pixels PIX arranged in the Y direction, the scanning signal lines GLS, GLR, and GLB for driving even-numbered pixels PIX are connected to one drive circuit 6, and the scanning signal lines GLS, GLR, and GLB for driving odd-numbered pixels PIX are connected to the other drive circuit 6. As another example, for example, there is a case where any one of the scanning signal lines GLS, GLR, and GLB is connected to one drive circuit 6 and the rest thereof is connected to the other drive circuit 6, for example, all the scanning signal lines GLS and GLR are connected to one drive circuit 6 and all the scanning signal lines GLB are connected to the other drive circuit 6.

The video signal line VL, the power supply lines PL1 and PL2, and the reset wiring RSL extend in the Y direction. The video signal line VL is connected to the control circuit 5 (see FIG. 1). The video signal Vsg and an initialization signal are supplied from the control circuit 5 to the video signal line VL. A high potential Pvdd is supplied from the control circuit 5 to the power supply line PL1. A low potential Puss lower than the high potential Pvdd is supplied from the control circuit 5 to the power supply line PL2. A reset signal Vrs is supplied from the control circuit 5 to the reset wiring RSL.

The control circuit 5 outputs a start pulse signal and a clock signal (not illustrated) to the drive circuit 6. The drive circuit 6 includes a plurality of shift register circuits, sequentially transfers a start pulse signal to a shift register circuit of a subsequent stage according to a clock signal, and sequentially supplies a scanning signal to each of the scanning signal lines GLS, GLR, and GLB.

The pixel circuit PC controls the LED element 20 according to the video signal Vsg supplied to the video signal line VL. In order to realize such control, the pixel circuit PC in the present embodiment includes a reset transistor (switching element) RST, a pixel selection transistor (switching element) SST, an output transistor (switching element) BCT, a drive transistor (switching element) DRT, a holding capacitor Cs, and an auxiliary capacitor Cad. The auxiliary capacitor Cad is an element provided to adjust the amount of light emission current, and may be unnecessary in some cases.

The reset transistor RST, the pixel selection transistor SST, the output transistor BCT, and the drive transistor DRT are switching elements made of thin film transistors (TFT). The conductivity type of the thin film transistor is not particularly limited, and for example, all the transistors may be constituted by N-channel TFTs, or at least one of the transistors may be constituted by P-channel TFTs.

In the present embodiment, the reset transistor RST, the pixel selection transistor SST, the output transistor BCT, and the drive transistor DRT are formed in the same step and in the same layer structure, and have a bottom gate structure using polycrystalline silicon for a semiconductor layer. As another example, the reset transistor RST, the pixel selection transistor SST, the output transistor BCT, and the drive transistor DRT may have a top gate structure. Note that, as the semiconductor layer, an oxide semiconductor, a polycrystalline GaN semiconductor, or the like may be used.

The reset transistor RST, the pixel selection transistor SST, the output transistor BCT, and the drive transistor DRT have a source electrode, a drain electrode, and a gate electrode. The gate electrode included in each transistor can be rephrased as a control electrode. The source electrode and the drain electrode included in each transistor can be simply rephrased as an electrode.

The drive transistor DRT and the output transistor BCT are connected in series with the LED element 20 between the power supply line PL1 and the power supply line PL2. The high potential Pvdd supplied to the power supply line PL1 is set to, for example, 10 V, and the low potential Pvss supplied to the power supply line PL2 is set to, for example, 1.5 V.

The drain electrode of the output transistor BCT is connected to the power supply line PL1. The source electrode of the output transistor BCT is connected to the drain electrode of the drive transistor DRT. The gate electrode of the output transistor BCT is connected to the scanning signal line GLB. The output transistor BCT is turned on and off by a control signal Gsb provided to the scanning signal line GLB. ON represents a conductive state, and OFF represents a non-conductive state. The output transistor BCT controls the light emission time of the LED element 20 based on the control signal Gsb.

The source electrode of the drive transistor DRT is connected to one electrode (here, the anode electrode 20EA) of the LED element 20. The other electrode (here, the cathode electrode 20EC) of the LED element 20 is connected to the power supply line PL2. The drive transistor DRT outputs a driving current corresponding to the video signal Vsg to the LED element 20.

The source electrode of the pixel selection transistor SST is connected to the video signal line VL. The drain electrode of the pixel selection transistor SST is connected to the gate electrode of the drive transistor DRT. The gate electrode of the pixel selection transistor SST is connected to the scanning signal line GLS functioning as a gate wiring for signal write control. The pixel selection transistor SST is turned on and off by a control signal Gss supplied from the scanning signal line GLS, and switches connection and disconnection between the pixel circuit PC and the video signal line VL. That is, when the pixel selection transistor SST is turned on, the video signal Vsg or the initialization signal of the video signal line VL is supplied to the gate electrode of the drive transistor DRT.

The source electrode of the reset transistor RST is connected to the reset wiring RSL. The drain electrode of the reset transistor RST is connected to the source electrode of the drive transistor DRT and the anode of the LED element 20. The gate electrode of the reset transistor RST is connected to the scanning signal line GLR functioning as a gate wiring for reset control. The reset transistor RST is turned on and off by a control signal Grs supplied from the scanning signal line GLR. When the reset transistor RST is switched on, the potentials of the source electrode of the drive transistor DRT and the anode of the LED element 20 can be reset by the reset signal Vrs of the reset wiring RSL. That is, the reset wiring RSL is a wiring for resetting the voltage of the LED element 20.

The holding capacitor Cs is connected between the gate electrode and the source electrode of the drive transistor DRT. The auxiliary capacitor Cad is connected between the source electrode of the drive transistor DRT and the power supply line PL2.

The drive circuit 6 sequentially supplies the control signals Gss, Grs, and Gsb to the scanning signal lines GLS, GLR, and GLB of each line (a series of pixels PIX arranged in the X direction) based on the start pulse signal and the clock signal. Based on the signal supplied from the control circuit 5 illustrated in FIG. 2, the control circuit 5 sequentially supplies the video signal Vsg and the initialization signal to each video signal line VL. The charge held in the holding capacitor Cs with the supply of the video signal Vsg is initialized with the supply of the initialization signal.

In the above configuration, the pixel circuit PC is driven by the control signals Gss, Grs, and Gsb supplied to the scanning signal lines GLS, GLR, and GLB, and the LED element 20 emits light with luminance corresponding to the video signal Vsg of the video signal line VL.

### Peripheral Structure of LED Element

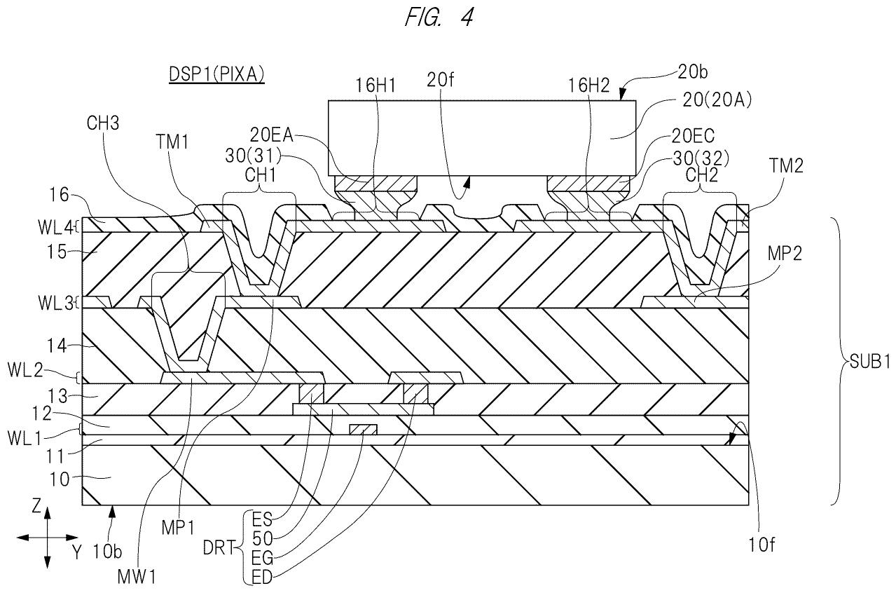

Next, a peripheral structure of an LED element arranged in the pixel PIX illustrated in FIG. 1 will be described. FIG. 3 is a perspective enlarged plan view illustrating an example of a peripheral structure of an LED element arranged in each of a plurality of pixels of the display device illustrated in FIG. 1. FIG. 4 is an enlarged cross-sectional view taken along a line A-A of FIG. 3.

In FIG. 3, a conductor pattern disposed in a wiring layer WL4 illustrated in FIG. 4 is indicated by a solid line. In FIG. 3, the outlines of the LED element 20 and the electrodes included in the LED element 20 are indicated by two-dot chain lines. A pixel PIXA, a pixel PIXB, and a pixel PIXC illustrated in FIG. 3 each have the same structure. Therefore, in FIG. 4, the structure of the pixel PIXA (see FIG. 3) is illustrated as a representative example, but the pixel PIXB and the pixel PIXC illustrated in FIG. 3 also have a similar cross-sectional structure.

In the following description, the terms terminal TM1 and terminal TM2 are used, but the term “terminal” means a conductor pattern including a terminal portion for electrically connecting an external device, and can be read as “terminal pattern”.

In the present embodiment, since the micro LED display device will be described, in the following description, a unit region in which the terminal TM1 and the terminal TM2 are arranged will be described using the term “pixel”. When the technique described below is applied to an electronic device other than the display device, the term “pixel” can be replaced with “region” and applied.

The pixel circuit PC illustrated in FIG. 2 is a circuit corresponding to each of the pixel PIXA, the pixel PIXB, and the pixel PIXC illustrated in FIG. 3. Therefore, each of the pixel PIXA, the pixel PIXB, and the pixel PIXC illustrated in FIG. 3 includes the reset transistor RST, the pixel selection transistor SST, the output transistor BCT, and the drive transistor DRT described with reference to FIG. 2. Similarly, each of the pixel PIXA, the pixel PIXB, and the pixel PIXC illustrated in FIG. 3 has the holding capacitor Cs and the auxiliary capacitor Cad described with reference to FIG. 2.

As illustrated in FIG. 4, the display device DSP1 includes a substrate structure SUB1 and an LED element (inorganic light emitting diode element) 20 mounted on the substrate structure SUB1. The substrate structure SUB1 of the display device DSP1 includes a plurality of insulating layers arranged between a plurality of wiring layers. The LED element 20 is mounted on the uppermost wiring layer WL4 among the plurality of wiring layers.

The substrate structure SUB1 of the display device DSP1 includes the substrate 10. The substrate 10 has a surface 10f and a surface 10b opposite to the surface 10f. The plurality of wiring layers and the plurality of insulating layers are laminated on the surface 10f of the substrate 10. The substrate 10 is, for example, a glass substrate made of glass. However, there are various modification examples of the material constituting the substrate 10, and for example, a resin substrate made of resin may be used.

The substrate structure SUB1 includes a transistor as a switching element. FIG. 4 illustrates the drive transistor DRT as an example of the switching element disposed on the substrate 10. However, the reset transistor RST, the pixel selection transistor SST, the output transistor BCT, and the drive transistor DRT described with reference to FIG. 2 are disposed on the substrate 10 (specifically, on the insulating layer 11). Each of the reset transistor RST, the pixel selection transistor SST, the output transistor BCT, and the drive transistor DRT illustrated in FIG. 2 has a structure similar to that of the drive transistor DRT illustrated in FIG. 4 described later.

As illustrated in FIG. 3, the display device DSP1 includes a plurality of LED elements 20. In FIG. 3, among the plurality of LED elements 20 included in the display device, an LED element 20A, an LED element 20B arranged next to the LED element 20A, and an LED element 20C arranged next to the LED element 20B are illustrated.

As illustrated in FIG. 4, the LED element 20 includes a surface 20f and a surface 20b opposite to the surface 20f. The LED element 20 includes a plurality of (two in FIG. 3) electrodes arranged on the surface 20f. The plurality of electrodes included in the LED element 20 include the anode electrode 20EA and the cathode electrode 20EC. The anode electrode 20EA is electrically connected to the terminal TM1 via a bump electrode 31. The cathode electrode 20EC is electrically connected to the terminal TM2 via a bump electrode 32.

Note that, in the present embodiment, as an example of the LED element, an example in which the anode electrode 20EA and the cathode electrode 20EC are formed so as to be separated from each other on one surface 20f of the LED element 20 will be described. However, as a modification example with respect to the present embodiment, there is a case where one of the anode electrode 20EA and the cathode electrode 20EC is formed on the surface 20f of the LED element 20, and the other of the anode electrode 20EA and the cathode electrode 20EC is formed on the surface 20b located on the opposite side of the surface 20f. In the case of this modification example, one of the terminal TM1 and the terminal TM2 illustrated in FIG. 3 is formed in the substrate structure.

Among the conductor patterns included in the substrate structure SUB1, the terminal TM1 and the terminal TM2 are conductor patterns including a portion functioning as a “terminal” for electrically connecting the LED element 20 and the substrate structure SUB1. Each of the terminal TM1 and the terminal TM2 is disposed on the substrate 10.

The display device DSP1 displays an image by driving each of the plurality of LED elements 20 mounted on the substrate structure SUB1.

In the case of an example illustrated in FIG. 4, the plurality of wiring layers included in the display device DSP1 includes a wiring layer WL4, a wiring layer WL3, a wiring layer WL2, and a wiring layer WL1 which are sequentially laminated from the wiring layer WL4 toward the substrate 10. The plurality of insulating layers included in the display device DSP1 includes insulating layers 11, 12, 13, 14, 15, and 16 sequentially laminated from the surface 10f of the substrate 10.

The insulating layer 11 is a base layer of a thin film transistor and is an inorganic insulating layer made of an inorganic material. The wiring layer WL1 is disposed on the insulating layer 11 and covered with the insulating layer 12. The conductor pattern formed in the wiring layer WL1 includes the gate electrode EG illustrated in FIG. 4, the scanning signal lines GLB, GLS, and GLR described with reference to FIG. 2, and the like. The insulating layer 12 is also an inorganic insulating layer made of an inorganic material. A portion, which is disposed between the gate electrode EG of the transistor and a semiconductor layer 50, of the insulating layer 12 functions as a gate insulating film.

The drive transistor DRT including the gate electrode EG includes the semiconductor layer 50, the gate electrode EG, a source electrode ES, and a drain electrode ED. In the example illustrated in FIG. 4, a thin film transistor having a bottom gate structure is illustrated as an example, but the thin film transistor may have a top gate structure as described above. The gate electrode EG is disposed on the insulating layer 11. The semiconductor layer 50 is disposed on the insulating layer 12. A part of the semiconductor layer 50 corresponds to a source region, and the source electrode ES is connected to the source region. The other part of the semiconductor layer 50 corresponds to a drain region, and the drain electrode ED is connected to the drain region. A region between the source region and the drain region functions as a channel region.

The wiring layer WL2 is disposed on the insulating layer 13 covering the drive transistor DRT. The insulating layer 13 is an inorganic insulating layer made of an inorganic material. The conductor pattern formed in the wiring layer WL2 includes a wiring connected to each of the plurality of transistors. For example, as illustrated in FIG. 4, a wiring pattern MW1 connected to the source electrode ES of the drive transistor DRT is included in the wiring layer WL2. The conductor pattern formed in the wiring layer WL2 includes the video signal line VL, the power supply line PL1, the power supply line PL2, and the reset wiring RSL illustrated in FIG. 2.

The wiring layer WL2 includes the wiring pattern MW1 electrically connected to a conductor pattern MP1 through a contact hole CH3 formed in the insulating layer 14, and electrically connected to the electrode (the source electrode ES) of the drive transistor DRT.

Each of the insulating layer 14 covering the wiring layer WL2 and the insulating layer 15 laminated on the insulating layer 14 is an organic insulating film made of an organic material. The insulating layer 14 is an insulating layer disposed between the wiring layer WL2 and the wiring layer WL3. The insulating layer 15 is an insulating layer disposed between the wiring layer WL3 and the wiring layer WL4. As illustrated in FIG. 4, a contact hole is used for electrical connection between the wiring layer WL2 and the wiring layer WL3 and for electrical connection between the wiring layer WL3 and the wiring layer WL4. The organic insulating layer is excellent in filling characteristics with respect to an opening (for example, a contact hole) as compared with the inorganic insulating layer. In other words, in the case of the organic insulating layer, the upper surface is easily flattened even when there is an opening in the base. Therefore, each of the insulating layer 14 and the insulating layer 15 in which a large number of contact holes are formed is made of As an organic material. the organic material constituting the insulating layer 14 and the insulating layer 15, for example, an acrylic resin can be exemplified.

FIG. 4 illustrates contact holes CH1, CH2, and CH3 among a large number of contact holes included in the substrate structure SUB1. The contact hole CH1 is an opening connecting the terminal TM1 and the conductor pattern MP1 of the wiring layer WL3. The contact hole CH2 is an opening connecting the terminal TM2 and a conductor pattern MP2 of the wiring layer WL3. The contact hole CH3 is an opening connecting the conductor pattern MP1 of the wiring layer WL3 and the wiring pattern MW1 of the wiring layer WL2.

The wiring layer WL3 includes the conductor pattern MP1 electrically connected to the terminal TM1 via the contact hole CH1 formed in the insulating layer 15, and the conductor pattern MP2 made of the same metal as the conductor pattern MP1 and electrically connected to the terminal TM2 via the contact hole CH2 formed in the insulating layer 15.

The conductor pattern MP1 has, on the bottom surface of the contact hole CH1, a flat portion connected to the terminal TM1 and a contact portion embedded in the contact hole CH3 and connected to the wiring layer WL2. As illustrated in FIG. 3, the conductor pattern MP2 is a large-area pattern extending over the plurality of pixels PIX.

Each of the conductor pattern MP1, the conductor pattern MP2, the terminal TM1, and the terminal TM2 illustrated in FIG. 4 is made of, for example, the same metal material. In the case of the present embodiment, each of the conductor pattern MP1, the conductor pattern MP2, the terminal TM1, and the terminal TM2 is a laminated film of a titanium layer made of titanium, an aluminum layer made of aluminum, and a titanium layer made of titanium.

The wiring layer WL4 is an uppermost wiring layer among the plurality of wiring layers. The wiring layer WL4 includes the terminal (conductor pattern) TM1 electrically connected to the anode electrode 20EA of the LED element 20A and the terminal (conductor pattern) TM2 electrically connected to the cathode electrode 20EC of the LED element 20A.

The wiring layer WL4 is covered with an insulating layer 16 made of an inorganic material. The insulating layer 16 is an inorganic insulating layer made of, for example, silicon nitride or silicon oxide. Each of the terminal TM1 and terminal TM2 is covered with the insulating layer 16.

Specifically, the terminal TM1 has a terminal portion (also referred to as a flat portion) exposed from the insulating layer 16 in an opening 16H1 of the insulating layer 16, and a contact portion embedded in the contact hole CH1 and connected to the wiring layer WL3. The contact portion is covered with the insulating layer 16. Similarly, the terminal TM2 has a terminal portion exposed from the insulating layer 16 in an opening 16H2 of the insulating layer 16 and a contact portion embedded in the contact hole CH2 and connected to the wiring layer WL3. The contact portion is covered with the insulating layer 16. Each of the terminals TM1 and TM2 is an external terminal of the substrate structure SUB1.

The opening 16H1 is partially formed in the insulating layer 16. The terminal TM1 disposed in the wiring layer WL4 is connected to the bump electrode 31 in the opening 16H1 formed in the insulating layer 16. Similarly, the terminal TM2 disposed in the wiring layer WL4 is connected to the bump electrode 32 in the opening 16H2 formed in the insulating layer 16.

The bump electrode 31 is electrically connected to the terminal TM1. The bump electrode 32 is electrically connected to the terminal TM2. The anode electrode 20EA of the LED element 20A is electrically connected to the terminal TM1 via the bump electrode 31. The cathode electrode 20EC of the LED element 20A is electrically connected to the terminal TM2 via the bump electrode 32. Each of the bump electrode 31 and the bump electrode 32 is made of, for example, tin.

### Details of Terminal and Bump Electrode

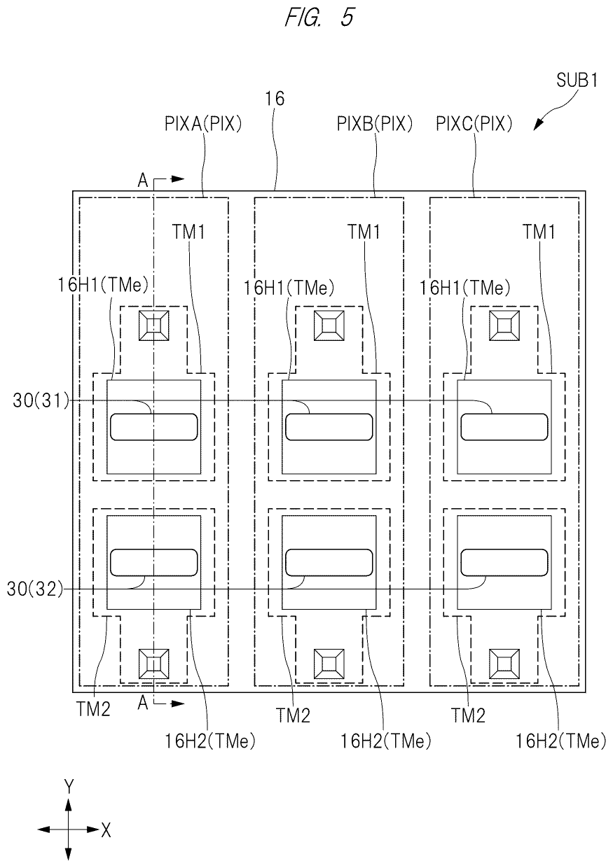

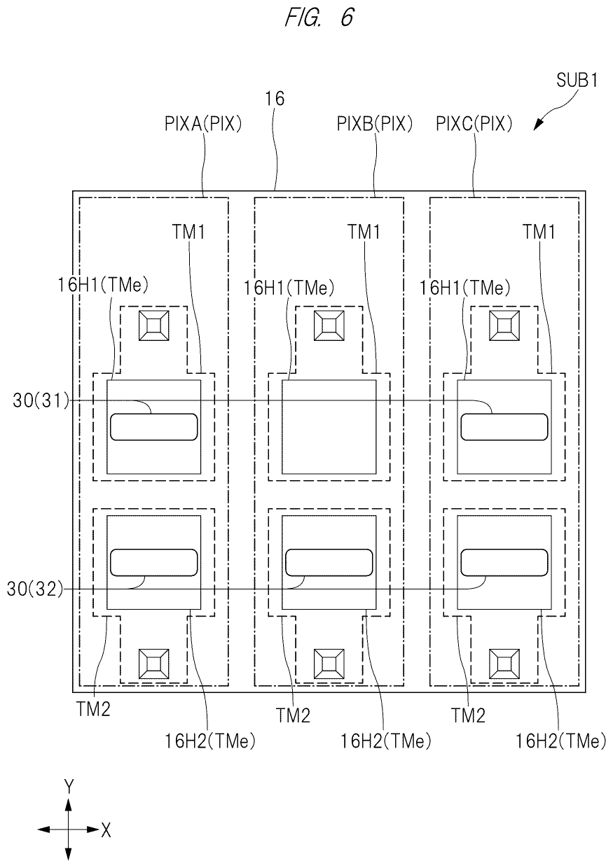

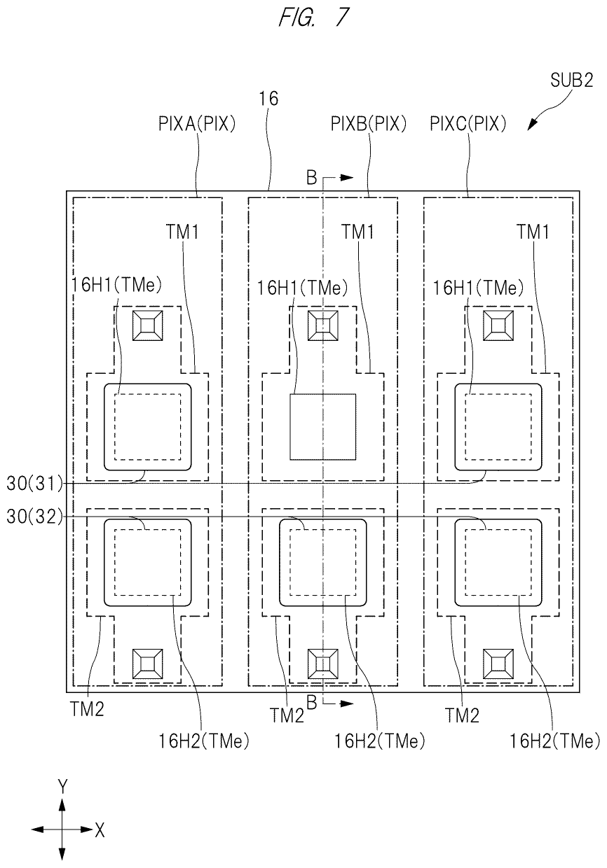

Next, a detailed structure of the terminal and the bump electrode illustrated in FIGS. 3 and 4 will be described. FIG. 5 is an enlarged plan view illustrating an upper surface of a substrate structure before mounting of the LED element illustrated in FIG. 3. FIG. 6 is an enlarged plan view illustrating a modification example with respect to FIG. 5. FIG. 7 is an enlarged plan view illustrating a study example relative to FIG. 6. FIG. 8 is an enlarged cross-sectional view taken along a line A-A of FIG. 5. FIG. 9 is an enlarged cross-sectional view taken along a line B-B of FIG. 7.

Each of the plurality of bump electrodes 30 (the plurality of bump electrodes 31 and the plurality of bump electrodes 32) illustrated in each of FIGS. 5 to 7 is formed on an exposed surface TMe of the terminal TM1 or TM2 by, for example, a plating method. Each of the plurality of bump electrodes 30 is formed so as to be separated from each other.

In the plan view, the substrate structure SUB1 includes a plurality of regions (pixels PIX), and each of the plurality of regions (pixels PIX) includes the terminal TM1 (and the terminal TM2) and the bump electrode 30.

As illustrated in FIG. 6 or 7, there is a case where a part of the plurality of bump electrodes 30 is not formed due to a defect or the like during a manufacturing process. In examples illustrated in FIGS. 6 and 7, the bump electrode 30 is not formed in the opening 16H1 of the pixel PIXB among the plurality of openings 16H1. In this case, even when the LED element 20B illustrated in FIG. 3 is mounted on the pixel PIXB, there is a high possibility that the pixel PIXB does not operate as designed since the electrical connection reliability between the LED element 20 and the terminal TM1 is low.

Therefore, as illustrated in FIGS. 6 and 7, when the pixel PIX in which the bump electrode 30 is not formed is found, it is necessary to cope with the pixel PIX. For example, the following method can be exemplified as the above correspondence. For example, when the pixel PIX in which the bump electrode 30 is not formed is found, the pixel is repaired before the LED element 20 (see FIG. 3) is mounted, and the bump electrode 30 is formed. In other words, a step of forming the bump electrode 30 in the pixel PIX in which the bump electrode 30 is not formed is performed. In this case, although the manufacturing process is added, since each of the plurality of pixels PIX can be normally operated, the reliability of the display device can be improved.

Alternatively, when the pixel PIX in which the bump electrode 30 is not formed is found, the LED element 20 (see FIG. 3) is not mounted on the pixel, and processing is performed as a blank pixel. In the case of a display device capable of performing color display by a set of a plurality of sub-pixels (for example, a set of a red sub-pixel, a green sub-pixel, and a blue sub-pixel), when a sub-pixel in which the bump electrode 30 is not formed is found, the LED element 20 is not mounted on each of the plurality of sub-pixels including the sub-pixel, and processing is performed as a blank pixel.

Note that when the LED element 20 (see FIG. 3) is mounted on the pixel PIX in which the bump electrode 30 is not formed, uncontrollable light emission may be generated according to the electrical connection state between the terminal and the LED element 20. In the case of performing processing as a blank pixel, the display is in a state where a defective portion (for example, a black spot or a white spot) is included in the image, but the influence on the quality of a display image is relatively small as compared with a case where uncontrollable light emission occurs.

As described above, when the pixel PIX in which a part of the plurality of bump electrodes 30 is not formed is generated due to a defect or the like during the manufacturing process, it is possible to take a necessary measure by finding the pixel PIX before mounting the LED element 20. However, according to the study by the inventor of the present application, it has been found that it is difficult to identify the presence or absence of the bump electrode 30 depending on the shape of the bump electrode 30.

For example, in the case of using the insulating layer 16 itself as a mask when the bump electrode 30 is formed by a plating method as in a substrate structure SUB2 illustrated in FIGS. 7 and 9, the bump electrode 30 is formed so as to cover the entire opening 16H2. On the other hand, as illustrated in FIG. 9, when the contact state of a plating solution is insufficient in the opening 16H1, the bump electrode 30 may not be formed on the opening 16H1, or the thickness of the bump electrode 30 may not be sufficiently thick. When the thickness of the bump electrode 30 is extremely thin, it is difficult to cause the bump electrode 30 to function.

In the example illustrated in FIG. 7, it is difficult to easily identify the presence or absence of the bump electrode 30 among the plurality of openings 16H1 and 16H2 for the following reasons. The planar shape of the exposed surface TMe and the planar shape of the bump electrode 30 are the same (in the example illustrated in FIG. 7, square). Since each of the terminal TM1 and the bump electrode 30 is made of a metal material, a difference in light reflectance is small. Since the entire opening 16H1 or the entire opening 16H2 is covered with the bump electrode 30, both the outer edge of the bump electrode 30 and the outer edges of the openings 16H1 and 16H2 cannot be visually recognized.

As illustrated in FIG. 7, since each of four corners of the bump electrode 30 has a round shape, strictly speaking, the planar shape of the bump electrode 30 is slightly different from the planar shape of the exposed surface TMe. However, since the difference is slight, it is difficult to identify the presence or absence of the bump electrode 30 due to the planar shape. In particular, in the step of determining the presence or absence of the bump electrode 30, when an image including a plurality of pixels PIX is acquired and the presence or absence of the bump electrode 30 is collectively determined for the plurality of pixels PIX, a clear difference is necessary in order to determine the presence or absence of the bump electrode 30 in relation to the resolution of the acquired image.

For example, the planar shape of the exposed surface TMe illustrated in FIG. 7 is a square having a length of one side of about 10 μm. Therefore, when the resolution of the acquired image is, for example, about 1 to 2 [μm/pix], only information of “a plurality of metal materials separated from each other exist in the insulating layer 16, and each of the plurality of metal materials being a square” can be obtained, and thus it is difficult to identify the presence or absence of the bump electrode 30. Note that, in the unit of the resolution described above, when the shape of one pixel of the acquired image is a square, the length of one side of a subject included in one pixel is expressed as [μm/pix].

In the step of determining the presence or absence of the bump electrode 30, it is conceivable to increase the resolution of the acquired image by reducing the imaging range for one time. However, when the imaging range is reduced, the presence or absence of the bump electrode 30 cannot be determined collectively for the plurality of pixels PIX. In this case, it takes a huge amount of time to determine the presence or absence of the bump electrode 30, which is not realistic. Therefore, in the case of the study example illustrated in FIG. 7, it can be said that it is substantially difficult to identify the presence or absence of the bump electrode 30.

In the case of the substrate structure SUB1 of the present embodiment illustrated in FIGS. 5, 6, and 8, the insulating layer 16 includes the opening 16H1 (and the opening 16H2) penetrating the insulating layer 16 in the thickness direction. The terminal TM1 has the exposed surface TMe exposed from the insulating layer 16 in the opening 16H1. In the plan view of the terminal TM1 (and the terminal TM2) viewed from above, the bump electrode 30 has a shape capable of identifying the presence or absence the bump electrode 30. The upper surface SUBt of the substrate structure SUB1 illustrated in FIG. 8 includes the upper surface of the insulating layer 16 and the exposed surfaces TMe of the terminal TM1 and the terminal TM2.

Specifically, in plan view, the area of the bump electrode 30 is smaller than the area of the exposed surface TMe, and the bump electrode 30 is formed on the exposed surface TMe in a state where the exposed surface TMe is visible.

In plan view, the planar shape of the bump electrode 30 and the planar shape of the exposed surface TMe are different from each other. In the examples illustrated in FIGS. 5 and 6, the bump electrode 30 has a rectangle, and the planar shape of the exposed surface TMe is a square.

As illustrated in FIGS. 5 and 6, when the planar shape of the bump electrode 30 and the planar shape of the exposed surface TMe are clearly different from each other, the boundary between the bump electrode 30 and the terminal TM1 (or the terminal TM2) can be identified even when each of the bump electrode 30 and the terminals TM1 and TM2 is made of a metal material.

For example, the planar shape of the exposed surface TMe illustrated in FIG. 5 is a square having a length of one side of about 10 to 15 μm. On the other hand, the planar shape of the bump electrode 30 is a rectangle having a short side length of about 2 to 5 μm. In this case, when the resolution of the acquired image is, for example, about 1 to 2 [μm/pix], the presence or absence of the bump electrode 30 can be sufficiently identified.

In the case of acquiring an image including a plurality of pixels PIX (for example, about several hundreds to tens of thousands of pixels PIX), the resolution of the acquired image can be set to about 1 to 2 [μm/pix]. Therefore, in the case of the present embodiment, the presence or absence of the bump electrode 30 can be collectively determined for the plurality of pixels PIX.

### Method of Manufacturing Electronic Device

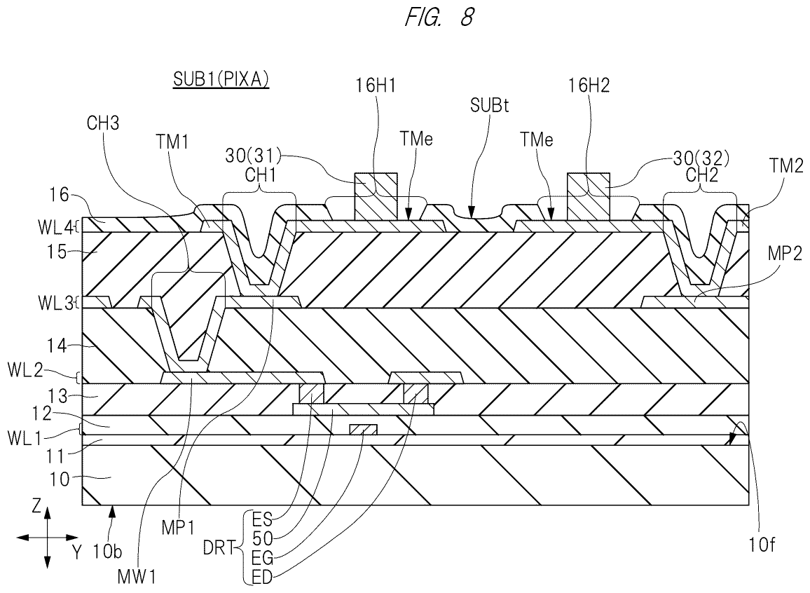

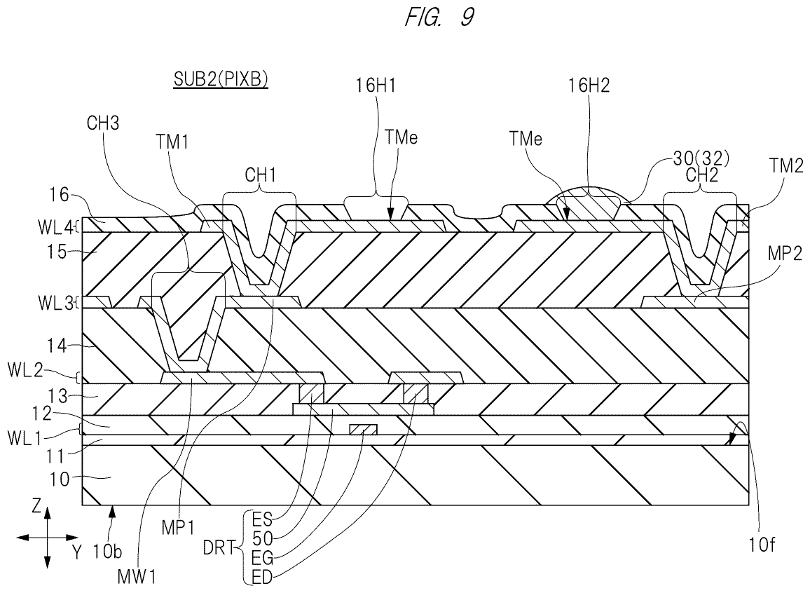

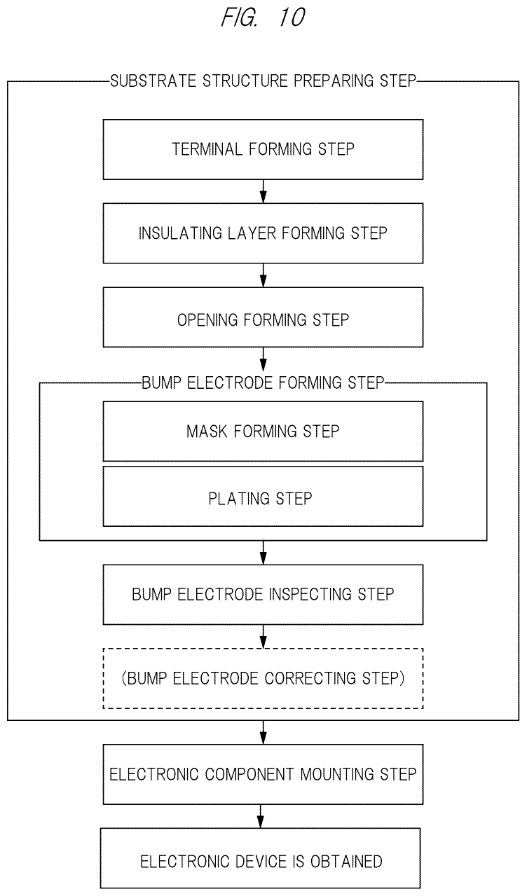

Next, as a method of manufacturing an electronic device of the present embodiment, a method of manufacturing the display device illustrated in FIG. 4 will be described. FIG. 10 is an explanatory diagram illustrating an example of a step flow of a method of manufacturing a display device according to an embodiment of the electronic device. As illustrated in FIG. 10, the method of manufacturing an electronic device of the present embodiment includes a substrate structure preparing step, a bump electrode forming step, and an electronic component mounting step. Note that, when the substrate structure before the electronic component is mounted is shipped as a semi-finished product, the electronic component mounting step can be omitted.

In the substrate structure preparing step, the substrate structure SUB1 illustrated in FIG. 8 is prepared. As illustrated in FIG. 10, the substrate structure preparing step includes a terminal forming step, an insulating layer forming step, an opening forming step, a bump electrode forming step, and a bump electrode inspecting step. Note that, as indicated by a dotted line in FIG. 10, when a pixel in which a bump electrode is not correctly formed is found in the bump electrode inspecting step, the substrate structure preparing step may include a bump electrode correcting step.

Note that, although not illustrated in FIG. 10, the substrate structure preparing step includes the following steps performed before the terminal forming step. That is, in the substrate structure preparing step, first, the substrate 10 made of glass or resin is prepared (substrate preparing step). The substrate structure preparing step includes a wiring layer laminating step of laminating the member illustrated in FIG. 2 or 4 on the substrate 10. In the wiring layer laminating step, the insulating layer 11, the wiring layer WL1, the insulating layer 12, a semiconductor element (for example, the drive transistor DRT illustrated in FIG. 4), the insulating layer 13, the wiring layer WL2, the insulating layer 14, the wiring layer WL3, and the insulating layer 15 are laminated in this order on the surface 10f of the substrate 10. The contact hole CH1 and the contact hole CH2 are formed in the insulating layer 15.

### Terminal Forming Step

In the terminal forming step illustrated in FIG. 10, the terminal TM1 and the terminal TM2 are formed on the insulating layer 15 illustrated in FIG. 8. Before this step, the contact hole CH1 and the contact hole CH2 are formed in advance in the insulating layer 15.

As described above, each of the terminal TM1 and the terminal TM2 is, for example, a laminated film of a titanium layer made of titanium, an aluminum layer made of aluminum, and a titanium layer made of titanium. Therefore, in the terminal forming step, the titanium layer, the aluminum layer, and the titanium layer are sequentially formed. As a method of forming the titanium layer and the aluminum layer, for example, a sputtering method can be exemplified. After the laminated film is formed, the terminal TM1 and the terminal TM2 are patterned as illustrated in FIGS. 5 and 8 by performing etching processing using a mask (not illustrated).

### Insulating Layer Forming Step

Next, in the insulating layer forming step illustrated in FIG. 10, the insulating layer 16 is formed so as to cover the entire terminals TM1 and TM2 illustrated in FIG. 8.

The insulating layer 16 is an inorganic insulating film such as silicon nitride as described above. Therefore, the flattening characteristic of the insulating layer 16 with respect to the irregularities is lower than that of the insulating layer 15 which is an organic insulating film. As a result, the insulating layer 16 has an upper surface having irregularities following the irregularities of the wiring layer WL4 formed on the insulating layer 15.

### Opening Forming Step

Next, in the opening forming step illustrated in FIG. 10, as illustrated in FIG. 8, the opening 16H1 and the opening 16H2 are formed in the insulating layer 16.

In the opening forming step, the opening 16H1 is formed to expose a part of the terminal TM1 from the insulating layer 16. In the opening forming step, the opening 16H2 is formed to expose a part of the terminal TM2 from the insulating layer 16.

A method of forming the opening 16H1 and the opening 16H2 is, for example, the following method. First, a resist mask (not illustrated) is formed, and then, openings are formed at positions overlapping formation scheduled regions of the opening 16H1 and the opening 16H2 in the resist mask using photolithography. Next, the insulating layer 16 exposed from the resist mask at the openings of the resist mask is removed by etching. As a result, the opening 16H1 and the opening 16H2 are formed. Thereafter, the resist mask is removed to obtain the insulating layer 16 illustrated in FIG. 8.

### Bump Electrode Forming Step

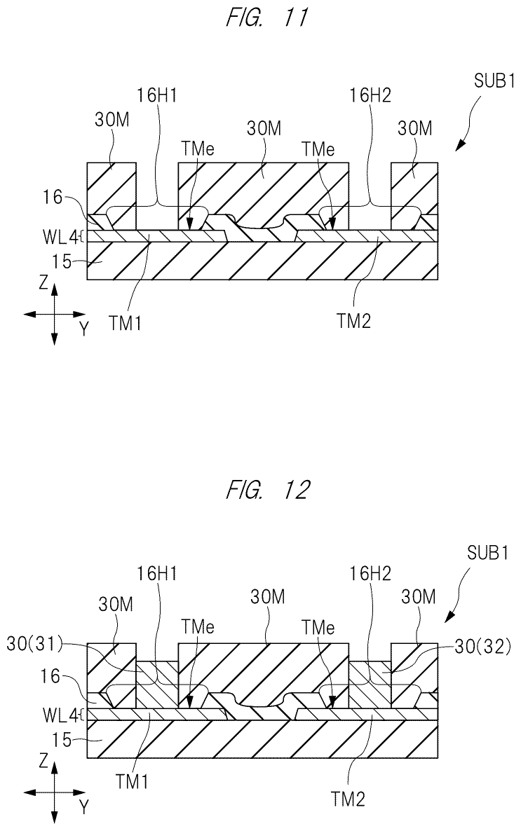

Next, in the bump electrode forming step illustrated in FIG. 10, the bump electrode 30 is formed on each of the terminal TM1 and the terminal TM2 illustrated in FIG. 8. In an example illustrated in FIG. 10, the bump electrode forming step includes a mask forming step and a plating step. FIG. 11 is an enlarged cross-sectional view illustrating a state where a mask is formed on an exposed surface of a terminal in a mask forming step illustrated in FIG. 10. FIG. 12 is an enlarged cross-sectional view illustrating a state where bump electrodes are formed in openings formed in the mask by a plating method in the plating step illustrated in FIG. 10.

As illustrated in FIG. 11, in the mask forming step of the bump electrode forming step, a mask 30M is formed on the substrate 10 (see FIG. 8). In the case of the present embodiment, the mask 30M is formed on the insulating layer 16 of the substrate structure SUB1. In the mask forming step, as illustrated in FIG. 11, openings are formed at a position overlapping the terminal TM1 and a position overlapping the terminal TM2. A part of the exposed surface TMe of the terminal TM1 and a part of the exposed surface TMe of the terminal TM2 are exposed from the mask 30M at the openings of the mask 30M. A method of forming the openings in the mask 30M is similar to the method of forming the opening 16H1 and the opening 16H2 described above.

As illustrated in FIG. 12, in the plating step of the bump electrode forming step, the bump electrode 30 is formed by a plating method. Examples of the plating method include electrolytic plating and electroless plating. When electrolytic plating or electroless plating is adopted, a plating film (a metal film formed by plating treatment) is selectively formed on the exposed surface of the metal.

In the case of the present embodiment, as illustrated in FIG. 11, the upper surface SUBt of the substrate structure SUB1 is covered with the mask 30M except for a part of the exposed surface TMe of the terminal TM1 and a part of the exposed surface TMe of the terminal TM2. Therefore, as illustrated in FIG. 12, in this step, the bump electrode 30 is selectively formed in the opening of the mask 30M.

Although illustrated in FIG. 10, the mask 30M illustrated in FIG. 12 is removed by, for example, etching as a mask removing step after the plating step. In this step, all of the mask 30M is removed. As a result, as illustrated in FIG. 8, the substrate structure SUB1 in which the bump electrode 30 is formed on each of the exposed surface TMe of the terminal TM1 and the exposed surface TMe of the terminal TM2, and a part of each of the exposed surface TMe of the terminal TM1 and the exposed surface TMe of the terminal TM2 is exposed from the bump electrode 30 and the insulating layer 16 is obtained.

### Bump Electrode Inspecting Step

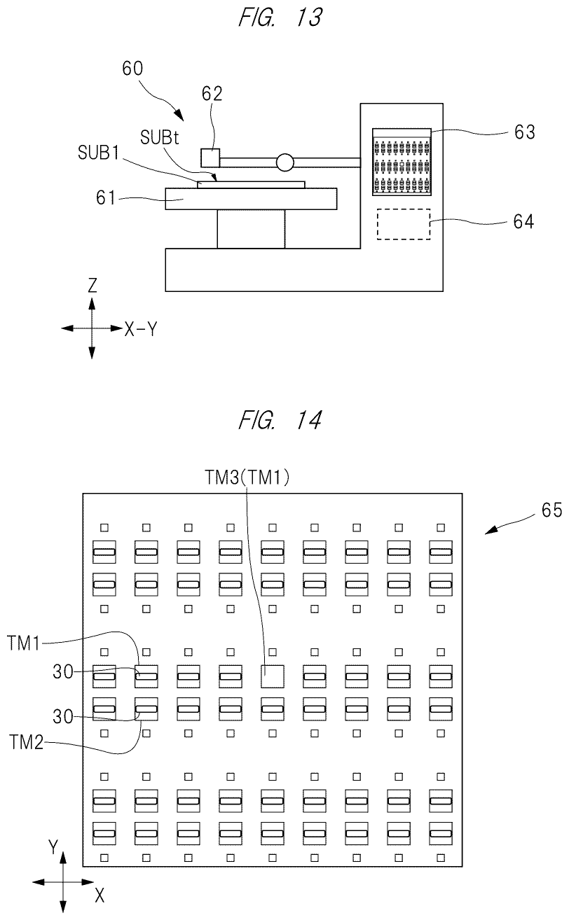

Next, in the bump electrode inspecting step illustrated in FIG. 10, it is inspected whether the bump electrode 30 is formed on each of the plurality of terminals TM1 and the plurality of terminals TM2 illustrated in FIGS. 5 and 6. FIG. 13 is an explanatory diagram illustrating an example of an inspection device inspecting a substrate structure in a bump electrode inspecting step illustrated in FIG. 10. FIG. 14 is an explanatory diagram illustrating an example of an image acquired by the inspection device illustrated in FIG. 13.

Note that FIG. 14 illustrates a state where terminals for 27 pixels are displayed in one image as an example, but the number of pixels displayed in one image is not limited to 27. The number of displayed pixels of one image varies depending on the specification of the resolution of a camera 62 (see FIG. 13), and for example, terminals of several hundred pixels to several tens of thousands of pixels may be displayed in one image. As described above, the work efficiency of the bump electrode inspecting step is improved as the number of pixels in which one image is displayed is increased within a range in which the presence or absence of the bump electrode can be identified.

In the bump electrode inspecting step, for example, the inspection is performed using an inspection device 60 illustrated in FIG. 13. The inspection device includes a stage 61 capable of supporting the substrate structure SUB1, the camera 62 capable of photographing the upper surface SUBt of the substrate structure SUB1, and a display unit (monitor) 63 capable of displaying an image acquired by the camera 62. In the case of the inspection device 60, a display image 65 illustrated in FIG. 14 as an example is displayed on a display unit 63.

Note that, in an example illustrated in FIG. 13, the inspection device 60 includes a determination circuit 64 for determining whether the bump electrode is formed on each of the plurality of terminals by using the image data acquired by the camera 62. In this case, since the quality determination itself of the plurality of terminals is performed by the determination circuit 64 of the inspection device 60, the display image 65 illustrated in FIG. 14 is not displayed on the display unit 63, and only the result of the quality determination may be simply displayed. However, the display image 65 is preferably displayed on the display unit 63 in that an operator can easily confirm the result of the quality determination.

In the bump electrode inspecting step, first, the substrate structure SUB1 is fixed on the stage 61. Next, the position of the camera 62 is moved along the X-Y plane to rest on the upper surface SUBt of the substrate structure SUB1. Next, a part of the upper surface SUBt is photographed by the camera 62 to acquire image data. The acquired image data is transmitted to an image processing circuit (not illustrated) and converted into image data. The image data is transmitted to the display unit 63, and the acquired display image 65 (see FIG. 14) is displayed on the display unit 63. The image data is transmitted to the determination circuit 64, and the determination circuit determines the quality of the display image 65.

The quality determination method is not particularly limited, but for example, the quality determination can be made based on whether a difference exceeding an allowable margin is detected in comparison with non-defective product image data acquired in advance. In the case of the display image 65 illustrated in FIG. 14, the bump electrode 30 is formed on each of the plurality of terminals TM1 and TM2, but the bump electrode 30 is not formed on a terminal indicated as a terminal TM3. Therefore, it is necessary to determine that the display image 65 is defective.

The resolution of the display image 65 is, for example, 2 [μm/pix] or less. As described above, the planar shape of the exposed surface TMe illustrated in FIGS. 5 and 6 is a square having a length of one side of about 10 to 15 μm. On the other hand, the planar shape of the bump electrode 30 is a rectangle having a short side length of about 2 to 5 μm. Therefore, in the display image 65 illustrated in FIG. 14, it can be identified that the bump electrode 30 is not formed on the terminal TM3. That is, in the case of the present embodiment, the presence or absence of the bump electrode 30 can be collectively determined for the plurality of pixels PIX (see FIG. 5).

### Bump Electrode Correcting Step

Next, in the bump electrode correcting step illustrated in FIG. 10, the bump electrode 30 is formed again for a terminal on which the bump electrode 30 is not formed, such as the terminal TM3 illustrated in the display image 65 illustrated in FIG. 14, for example.

In this step, for example, the bump electrode 30 is formed by a processing step similar to the bump electrode forming step described above. However, the bump electrode 30 (see FIG. 12) already formed on the substrate structure SUB1 (see FIG. 11) is covered with the mask 30M (see FIG. 11), and an opening is selectively formed in the mask 30M at a position overlapping with the terminal TM3 illustrated in FIG. 14.

Note that, when a pixel including the terminal TM3 on which the bump electrode 30 is not formed is processed as a blank pixel as described above, this step is omitted. In this case, coordinates of the terminal TM3 are stored, and an electronic component is not mounted on the terminal TM3 in the electronic component mounting step described later.

There is a case where the substrate structure SUB1 (see FIG. 4) before the electronic component is mounted is shipped as a semi-finished product. In this case, the electronic component mounting step illustrated in FIG. 10 is omitted, and the substrate structure SUB1 illustrated in FIG. 6 is subjected to necessary inspection and packing, and then shipment preparation s started. That: the substrate structure SUB1 as an electronic device is obtained after the state as illustrated in FIG. 5 is obtained by the bump electrode inspecting step (or the bump electrode correcting step) of FIG. 10.

Next, in the electronic component mounting step illustrated in FIG. 10, after the bump electrode forming step, as illustrated in FIG. 4, each of the bump electrode 31 and the bump electrode 32 is electrically connected to the electronic component (the LED element 20 in the example of FIG. 4). In this step, the bump electrode 31 and the bump electrode 32 are softened by, for example, laser irradiation. As a result, the bump electrode 31 is connected to the anode electrode 20EA of the LED element 20, and the bump electrode 32 is connected to the cathode electrode 20EC of the LED element. Note that, before this step, a solder film may be formed in advance on each of the anode electrode 20EA and the cathode electrode 20EC of the LED element 20 illustrated in FIG. 4. In this case, the bump electrode 31 and the bump electrode 32 made of solder can be easily integrated with the solder film formed on the electrode.

### Modification Example of Method of Identifying Presence or Absence of Bump Electrode

Next, a modification example of a method of identifying the presence or absence of the bump electrode will be described. In the modification example described below, a modification example of the substrate structure SUB1 described with reference to FIGS. 5, 6, and 8 will be described as an example of an electronic device. In each substrate structure of the modification example described below, when the LED element 20 illustrated in FIG. 4 is mounted on the bump electrode 30, a display device that is an electronic device is obtained.

In FIGS. 5, 6, and 7, the method of identifying the presence or absence of the bump electrode by the planar shape of the bump electrode 30 and the planar shape of the exposed surface TMe of the terminal being different from each other has been described. In FIGS. 5 and 6, as an example of the planar shape, an example in which the planar shape of the exposed surface TMe is a square and the planar shape of the bump electrode 30 is a rectangle has been described. Although not illustrated, as a modification example, the planar shape of the exposed surface TMe may be a rectangle, and the planar shape of the bump electrode 30 may be a square. There are various modification examples of the planar shape of bump electrode 30 and the planar shape of exposed surface TMe of the terminal.

However, when the planar shape of the bump electrode 30 and the planar shape of the exposed surface TMe of the terminal become complicated, it may be difficult to stably form the opening of the bump electrode 30 or the insulating layer 16 in relation to processing accuracy. In this respect, an embodiment in which one of the planar shape of the bump electrode 30 and the planar shape of the exposed surface TMe is a square and the other thereof is a rectangle is preferable from the viewpoint of ease of processing.

### Modification Example 1 of Exposed Surface of Terminal

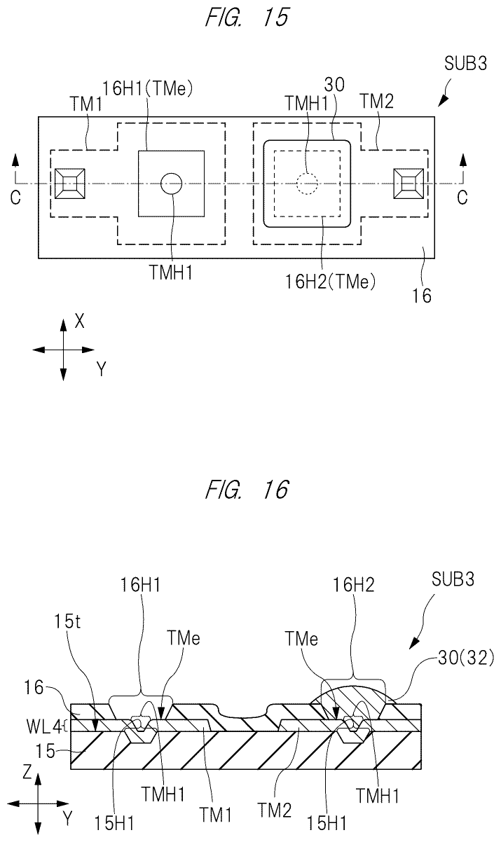

Next, as a modification example of the method of identifying the presence or absence of the bump electrode, a method of identifying the presence or absence of the bump electrode by devising the shape of the exposed surface of the terminal will be described. FIG. 15 is an enlarged plan view of a substrate structure as a modification example with respect to FIG. 5. FIG. 16 is an enlarged cross-sectional view taken along a line C-C of FIG. 15.

A substrate structure SUB3 illustrated in FIGS. 15 and 16 is different from the substrate structure SUB1 illustrated in FIGS. 5 and 8 in the following points. That is, the terminal TM1 (and the terminal TM2) of the substrate structure SUB3 includes a recess TMH1 formed in the exposed surface TMe. The bump electrode 30 is formed so as to cover the entire recess TMH1.

In the case of the present modification example, the recess TMH1 formed in the exposed surface TMe can be used as a mark for identifying the presence or absence of the bump electrode 30. When the bump electrode 30 is normally formed, the recess TMH1 is not recognized in the bump electrode inspecting step illustrated in FIG. 10. Therefore, when the recess TMH1 illustrated in FIG. 15 is recognized in the display image 65 (see FIG. 14) acquired in the bump electrode inspecting step, it can be determined that the bump electrode 30 is not formed on the terminal.

As described with reference to FIGS. 13 and 14, from the viewpoint of collectively inspecting a plurality of pixels, it is preferable that the pixels can be identified with a resolution of, for example, about 1 to 2 [μm/pix]. Therefore, the size of the recess TMH1 illustrated in FIG. 15 is preferably within a square region having a length of one side of about 2 μm to 4 μm. For example, in an example illustrated in FIG. 15, the planar shape of the exposed surface TMe is a square having a length of one side of about 10 μm. On the other hand, the diameter of the recess having a circular planar shape is preferably about 2 μm to 4 μm.

Meanwhile, although there are various modification examples in the method of forming the recess TMH1, in the case of the present embodiment, as illustrated in FIG. 16, a recess 15H1 is formed in the insulating layer 15 which is a base layer of the terminal TM1 (and the terminal TM2), and the recess TMH1 is formed following the recess 15H1.

The structure illustrated in FIG. 16 can be expressed as follows. That is, the wiring layer WL4 in which the terminal TM1 (and the terminal TM2) is formed is formed on the insulating layer 15 formed on the substrate 10 (see FIG. 8). The insulating layer 15 includes the recess 15H1 formed at a position overlapping the opening 16H1 (and the opening 16H2). The recess TMH1 of the terminal TM1 (and the recess TMH1 of the terminal TM2) is formed on the recess 15H1 of the insulating layer 15.

The terminal TM1 and the terminal TM2 are formed by, for example, the sputtering method as described above. In this case, when the recess 15H1 is formed on an upper surface of a base layer (that is, an upper surface 15t of the insulating layer 15), the recess TMH1 following the recess 15H1 is formed in the metal film laminated by the sputtering method. Therefore, in the case of the present modification example, a step of forming the recess 15H1 on the upper surface 15t of the insulating layer 15 is required before forming the wiring layer WL4, but an additional step is not required in the step of forming the wiring layer WL4 (in other words, the step of forming the terminal TM1).

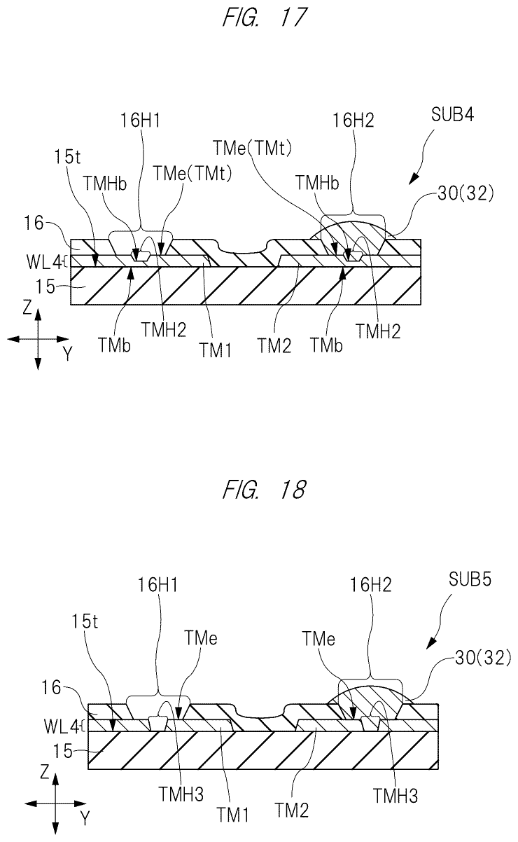

Note that, in the case of the substrate structure SUB3 illustrated in FIGS. 15 and 16, it is advantageous in that the film thickness of the terminal TM1 (and the terminal TM2) can be made constant as compared with a substrate structure SUB4 illustrated in FIG. 17 and a substrate structure SUB5 illustrated in FIG. 18 described below.

In the case of the present modification example, since the recess TMH1 is used as an identification mark for identifying the presence or absence of the bump electrode 30, the shape of the bump electrode 30 is not particularly limited. Therefore, as illustrated in FIG. 16, the bump electrode 32 is formed so as to cover the entire opening 16H2.

### Modification Example 2 of Exposed Surface of Terminal

Next, a modification example of the recess TMH1 described with reference to FIGS. 15 and 16 will be described. FIG. 17 is an enlarged cross-sectional view of a substrate structure as a modification example with respect to FIG. 16. FIG. 18 is an enlarged cross-sectional view of a substrate structure as another modification example relative to FIG. 16.

In the case of the substrate structure SUB3 illustrated in FIGS. 15 and 16, the embodiment has been described in which the recess TMH1 is formed in the wiring layer WL4 by forming the recess 15H1 in the insulating layer 15 which is the base layer. The substrate structure SUB4 illustrated in FIG. 17 and the substrate structure SUB5 illustrated in FIG. 18 are different from the substrate structure SUB3 illustrated in FIG. 16 in that the recess 15H1 (see FIG. 16) is not formed in the insulating layer 15, and a recess TMH2 or a recess TMH3 is directly formed in the terminal TM1 (and the terminal TM2).

In the case of the substrate structure SUB4 illustrated in FIG. 17, the terminal TM1 (and the terminal TM2) includes a surface (back surface) TMb located on the opposite side of the exposed surface TMe. The surface of the terminal TM1 (and the terminal TM2) is a flat surface compared with the exposed surface. In the case of the substrate structure SUB4, the recess TMH2 formed in a part of the exposed surface TMe includes a bottom surface TMHb located between the upper surface TMt and the surface TMb of the terminal TM1 (or the terminal TM2). In other words, in the case of the substrate structure SUB4, the recess TMH2 formed in a part of the exposed surface TMe does not penetrate the terminal TM1 (or the terminal TM2) in the thickness direction.

On the other hand, in the case of the substrate structure SUB5 illustrated in FIG. 18, the recess TMH3 is a through hole penetrating the terminal TM1 (or the terminal TM2) in the thickness direction.

The recess TMH2 illustrated in FIG. 17 and the recess TMH3 illustrated in FIG. 18 are formed to directly perform etching processing on the terminal TM1 and the terminal TM2. Therefore, the shapes of the open ends of the recess TMH2 and the recess TMH3 are likely to be an acute angle as compared with the shape of the open end of the recess TMH1 illustrated in FIG. 16. Therefore, in terms of ease of recognition in the bump electrode inspecting step illustrated in FIG. 10, the recess TMH2 illustrated in FIG. 17 or the recess TMH3 illustrated in FIG. 18 is superior to the recess TMH1 illustrated in FIG. 16.

Meanwhile, in the case of the recess TMH3 illustrated in FIG. 18, after a metal film is formed on the wiring layer WL4, for example, the recess TMH3 can be formed together when etching processing for patterning as in the terminal TM1 or the terminal TM2 indicated by a dotted line in FIG. 15 is performed. In this case, it is preferable in that addition of a new step accompanying formation of the recess TMH3 is not required.

On the other hand, in the case of the recess TMH2 illustrated in FIG. 17, in order to form the bottom surface TMHb, it is necessary to stop the etching in the middle with respect to the recess TMH2 or to decrease the etching rate with respect to the recess TMH2.

Note that, in each of the substrate structure SUB4 illustrated in FIG. 1 and the substrate structure SUB5 illustrated in FIG. 18, the bump electrode 32 is formed so as to cover the entire opening 16H2. This point is similar to the substrate structure SUB3 illustrated in FIG. 16.

### Modification Example of Insulating Layer around Exposed Surface of Terminal

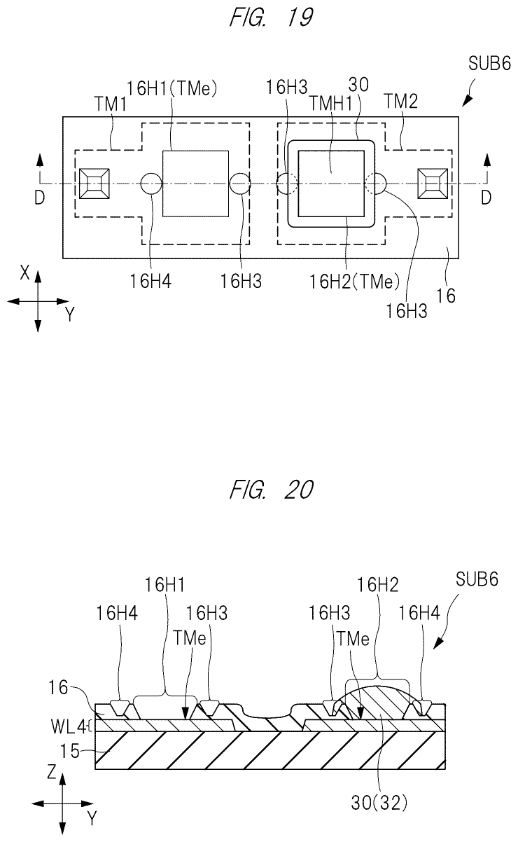

Next, as a modification example of the method of identifying the presence or absence of the bump electrode, a method of identifying the presence or absence of the bump electrode by devising the shape of the insulating layer disposed around the exposed surface of the terminal will be described. FIG. 19 is an enlarged plan view of a substrate structure as another modification example relative to FIG. 5. FIG. 20 is an enlarged cross-sectional view taken along a line D-D of FIG. 19.

In the case of a substrate structure SUB6 illustrated in FIGS. 19 and 20, it is possible to identify the presence or absence of the bump electrode by forming a mark in the insulating layer 16 around the opening 16H1 and the opening 16H2.

Specifically, the insulating layer 16 of the substrate structure SUB6 has a recess 16H3 formed outside the opening 16H1 (and outside the opening 16H2). The bump electrode 30 is formed so as to cover a part of the recess 16H3.

In the case of the substrate structure SUB6, the insulating layer 16 has a recess 16H4 located on the opposite side of the recess 16H3 with the opening 16H1 (or the opening 16H2) interposed therebetween. The bump electrode 30 is formed so as to cover a part of each of the recess 16H3 and the recess 16H4.

Although not illustrated, as a modification example with respect to FIGS. 19 and 20, for example, even in the case of an embodiment in which the recess 16H3 is not formed or an embodiment in which the recess 16H4 is not formed, the presence or absence of the bump electrode 30 can be identified. However, from the viewpoint of reliably performing identification, as illustrated in FIGS. 19 and 20, it is particularly preferable that the recess 16H3 and the recess 16H4 are disposed on opposite sides to each other with the exposed surface TMe interposed therebetween.

In the case of the present modification example, when the bump electrode 30 is normally formed, in the bump electrode inspecting step illustrated in FIG. 10, it is recognized that a part of each of the recess 16H3 and the recess 16H4 illustrated in FIG. 19 is missing. Alternatively, as a modification example, when the entire recess 16H3 and the entire recess 16H4 illustrated in FIG. 19 are covered with the bump electrode 30, in the bump electrode inspecting step, each of the recess 16H3 and the recess 16H4 illustrated in FIG. 19 is not recognized. Therefore, when the entire recess 16H3 or the entire recess 16H4 illustrated in FIG. 19 is recognized in the display image 65 (see FIG. 14) acquired in the bump electrode inspecting step, it can be determined that the bump electrode 30 is not correctly formed on the terminal.

Similarly to each embodiment described above, also in the present modification example, from the viewpoint of collectively inspecting a plurality of pixels, it is preferable that the pixels can be identified with a resolution of, for example, about 1 to 2 [μm/pix]. Therefore, the size of each of the recess 16H3 and the recess 16H4 illustrated in FIG. 19 is preferably within a square region having a length of one side of about 2 μm to 4 μm. For example, in an example illustrated in FIG. 15, the planar shape of the exposed surface TMe is a square having a length of one side of about 10 μm. On the other hand, the diameter of the recess having a circular planar shape is preferably about 2 μm to 4 μm.

As illustrated in FIG. 20, each of the recess 16H3 and the recess 16H4 does not penetrate the insulating layer 16 in the thickness direction. Therefore, the terminal TM1 (and the terminal TM2) is not exposed from the insulating layer 16 at a position overlapping the recess 16H3 or the recess 16H4.

When the terminal TM1 is exposed from the insulating layer 16 at a position overlapping the recess 16H3 or the recess 16H4, the bump electrode 30 is also formed at the exposed portion, so that the area of the bump electrode 30 increases. In a case where the arrangement pitch of the plurality of terminals TM1 and TM2 is small, when the surface area of the bump electrode 30 increases, there is a concern that the bump electrodes 30 adjacent to each other are short-circuited. Therefore, as illustrated in FIG. 20, it is preferable that the terminal TM1 (and the terminal TM2) is not exposed from the insulating layer 16 at a position overlapping the recess 16H3 or the recess 16H4.

As a modification example with respect to FIG. 19, there is an embodiment in which the entire recess 16H3 and the entire recess 16H4 are covered with the bump electrode 30. However, similarly to the above, from the viewpoint of avoiding the plane area of the bump electrode 30 from becoming extremely large, as illustrated in FIG. 19, it is preferable that a part of each of the recess 16H3 and the recess 16H4 is covered with the bump electrode 30, and the other part is exposed from the bump electrode 30.

### Another Modification Example of Method of Identifying Presence or Absence of Bump Electrode

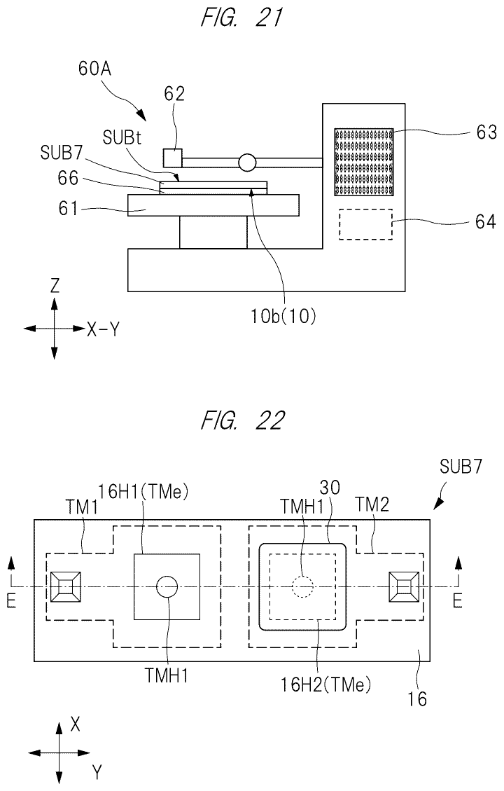

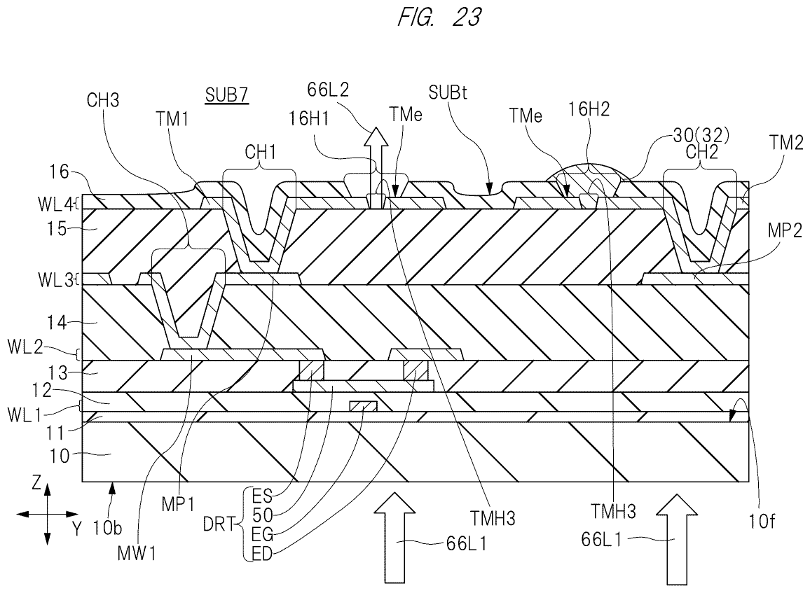

Next, as another modification example of the method of identifying the presence or absence of the bump electrode, a method of identifying the presence or absence of the bump electrode while emitting light from the back surface of the substrate structure will be described. FIG. 21 is an explanatory diagram illustrating a modification example with respect to FIG. 13. FIG. 22 is an enlarged plan view of a substrate structure as another modification example relative to FIG. 5. FIG. 23 is an enlarged cross-sectional view taken along a line E-E of FIG. 22.

In the case of the present modification example, in the bump electrode inspecting step illustrated in FIG. 10, as schematically illustrated in FIG. 23, the presence or absence of the bump electrode 30 is determined by emitting light 66L1 from the surface 10b of the substrate 10 and recognizing the presence or absence of light 66L2 leaking from the upper surface SUBt of the substrate structure SUB7.

The bump electrode inspecting step of the present modification example is performed by, for example, an inspection device 60A illustrated in FIG. 21. The inspection device 60A is similar to the inspection device 60 described with reference to FIG. 13, except that a light source 66 is disposed between the surface 10b of the substrate structure SUB7 and the stage 61. The light source 66 is an optical device capable of irradiating the surface 10b of the substrate structure SUB7 with light.

Note that the position of the light source 66 is not limited between the surface 10b of the substrate structure SUB7 and the stage 61 as long as the surface 10b can be irradiated with light.

The structure of the substrate structure SUB7 is similar to the structure of the substrate structure SUB5 described with reference to FIG. 18. That is, as illustrated in FIG. 23, the substrate structure SUB7 includes the substrate 10 including the surface 10f and the surface 10b opposite to the surface 10f, the wiring layer WL4 disposed on the surface 10f of the substrate 10, the terminal TM2 (and the terminal TM1) formed on the wiring layer WL4, the insulating layer 16 covering the terminal TM2, and the bump electrode 30 electrically connected to the terminal TM2.

The insulating layer 16 includes the opening 16H2 (and the opening 16H1) penetrating the insulating layer 16 in the thickness direction (Z direction). The terminal TM2 has the exposed surface TMe exposed from the insulating layer 16 in the opening 16H2. The terminal TM1 has the exposed surface TMe exposed from the insulating layer 16 in the opening 16H1. A member between the exposed surface TMe of the terminal TM2 and the surface 10b of the substrate is disposed in a state where the light can be emitted from the opening to the bump electrode when the light 6611 is emitted from the surface 10b of the substrate 10 toward the exposed surface TMe.

In the case of the substrate structure SUB7, the terminal TM1 (and the terminal TM2) includes the recess TMH3 formed on the exposed surface TMe and penetrating the terminal TM1 (or the terminal TM2) in the thickness direction. The bump electrode 30 is formed so as to cover the entire recess TMH3. Each of the insulating layers 11, 12, 13, 14, and 15 illustrated in FIG. 23 is made of a light-transmitting material. On the other hand, the insulating layer 16 is made of a light-shielding material. Note that, when the insulating layer 16 is made of a light-transmitting material, it is necessary to form a light shielding film (not illustrated) between the insulating layer 16 and the insulating layer 15 or on the insulating layer 16.

In the case of the substrate structure SUB7, when the bump electrode 30 is correctly formed, the light 66L2 is not detected. On the other hand, when the bump electrode 30 is not formed as in the terminal TM1 in FIG. 23, the light 66L2 leaks onto the upper surface SUBt via the recess TMH3. Therefore, in the bump electrode inspecting step, the presence or absence of the bump electrode 30 can be determined by detecting light leaking.

Note that a material constituting an element such as the drive transistor DRT illustrated in FIG. 23 may not have light-transmitting property. Even if a steel member of an element formed on the substrate 10 is made of a light-shielding material, the area is not large. Therefore, when each of the insulating layers 11, 12, 13, 14, and 15, which are large-area members, has light-transmitting property, the light 66L1 incident from the surface 10b goes around the light-shielding element and reaches the upper surface SUBt.

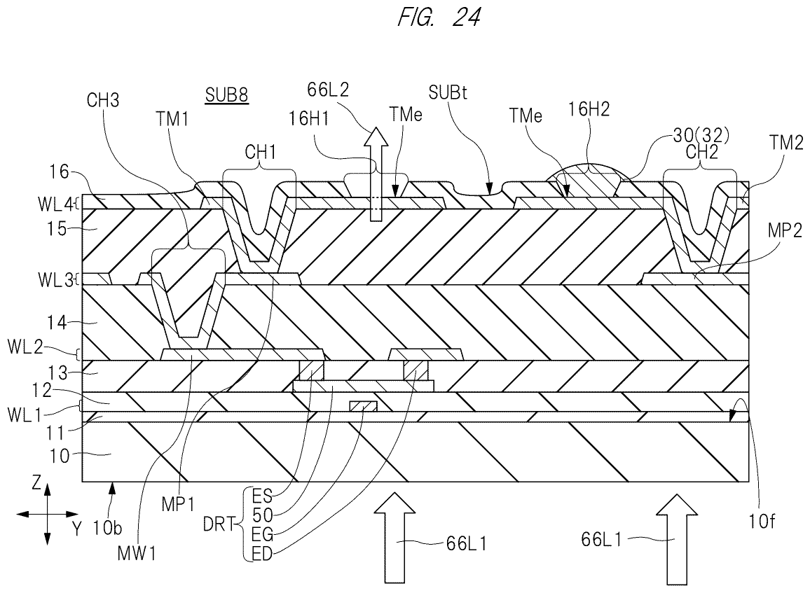

FIG. 24 is an enlarged cross-sectional view illustrating a modification example with respect to FIG. 23. In the case of a substrate structure SUB8 illustrated in FIG. 24 is different from the substrate structure SUB7 illustrated in FIG. 23 in that the recess TMH3 illustrated in FIG. 23 is not formed and each of the terminal TM1 and the terminal TM2 has light-transmitting property.

Each of the terminal TM1 and the terminal TM2 included in the substrate structure SUB8 is made of an electrode material called a so-called “transparent electrode”. Typical examples of the transparent electrode include indium tin oxide (ITO). However, the light-transmitting material is not limited to ITO, and various modification examples can be applied.

In the case of the substrate structure SUB8, as illustrated in FIG. 24, since the light 66L2 is transmitted through the terminal TM1, the opening 16H1 and the opening 16H2 themselves function as marks for identifying the presence or absence of the bump electrode 30.

In the case of the substrate structure SUB7 illustrated in FIG. 23 and the substrate structure SUB8 illustrated in FIG. 24, the presence or absence of the bump electrode 30 is determined by detecting the light 66L2, and thus, the detection sensitivity is high as compared with each embodiment described with reference to FIGS. 5 to 20. Therefore, for example, as compared with the case of performing determination using the display image 65 illustrated in FIG. 14, the range of the region that can be determined at one time can be increased. In this case, the efficiency of the bump electrode inspecting step can be improved.

In the case of the substrate structure SUB7 illustrated in FIG. 23 and the substrate structure SUB8 illustrated in FIG. 24, the bump electrode 30 is formed so as to cover the entire opening 16H2, similarly to the substrate structures illustrated in FIGS. 6 to 18.

In the case of the substrate structure SUB7 illustrated in FIG. 23 and the substrate structure SUB8 illustrated in FIG. 24, similarly to substrate structure SUB1 illustrated in FIGS. 5 and 6, in plan view, the substrate structure SUB7 (and the substrate structure SUB8) has the plurality of pixels (regions) PIX (see FIG. 5), and each of the plurality of pixels (regions) PIX includes the terminal TM2 and the bump electrode 30.

The embodiments and the typical modification examples have been explained above; however, the above-described technique is applicable to not only the exemplified modification examples but also various modification examples. For example, the above-described modification examples may be combined with one another.

In the scope of the idea of the present disclosure, various modification examples and alteration examples could have been easily anticipated by those who are skilled in the art, and it would be understood that these various modification examples and alteration examples are within the scope of the present disclosure. For example, the ones obtained by appropriate addition, removal, or design-change of the components to/from/into each of the above-described embodiments by those who are skilled in the art or obtained by addition, omitting, or condition-change of the step to/from/into each of the above-described embodiments are also within the scope of the present disclosure as long as they include the idea of the present disclosure

The present disclosure is applicable to an electronic device such as a display device.

1. An electronic device comprising:
a substrate including a first surface and a second surface opposite to the first surface;
a wiring layer disposed on the first surface of the substrate;
a terminal formed on the wiring layer;
a first insulating layer covering the wiring layer; and
a bump electrode electrically connected to the terminal,
wherein the first insulating layer includes a first opening penetrating the first insulating layer in a thickness direction,
wherein the terminal has an exposed surface exposed from the first insulating layer in the first opening, and
wherein, in plan view of the terminal viewed from above, at least one of the first insulating layer, the bump electrode, and the terminal has a shape capable of identifying presence or absence of the bump electrode.

2. The electronic device according to claim 1,
wherein, in the plan view, an area of the bump electrode is smaller than an area of the exposed surface, and the bump electrode is formed on the exposed surface in a state where the exposed surface is visible.

3. The electronic device according to claim 2,
wherein, in the plan view, a planar shape of the bump electrode and a planar shape of the exposed surface are different from each other.

4. The electronic device according to claim 1,
wherein, the terminal includes a first recess formed in the exposed surface, and
wherein the bump electrode is formed so as to cover the entire first recess.

5. The electronic device according to claim 4,
wherein the wiring layer is formed on a second insulating layer formed on the substrate,
wherein the second insulating layer includes a second recess formed at a position overlapping the first opening, and
wherein the first recess of the terminal is formed on the second recess of the second insulating layer.

6. The electronic device according to claim 4,
wherein the terminal includes a third surface located on an opposite side of the exposed surface, and
wherein the third surface of the terminal is a flat surface as compared with the exposed surface.

7. The electronic device according to claim 4,
wherein the first recess is a through hole penetrating the terminal in the thickness direction.

8. The electronic device according to any one of claim 5,
wherein the bump electrode is formed so as to cover the entire first opening.

9. The electronic device according to claim 1,
wherein the first insulating layer has a third recess formed outside the first opening, and
wherein the bump electrode is formed so as to cover the third recess.

10. The electronic device according to claim 9,
wherein the first insulating layer has a fourth recess located on an opposite side of the third recess with the first opening interposed between the fourth recess and the third recess, and
wherein the bump electrode is formed so as to cover the third recess and the fourth recess.

11. The electronic device according to claim 1,
wherein, in the plan view, the electronic device has a plurality of regions, and
wherein each of the plurality of regions includes the terminal and the bump electrode.

12. An electronic device comprising:
a substrate including a first surface and a second surface opposite to the first surface;
a wiring layer disposed on the first surface of the substrate;
a terminal formed on the wiring layer;
a first insulating layer covering the wiring layer; and
a bump electrode electrically connected to the terminal,
wherein the first insulating layer includes a first opening penetrating the first insulating layer in a thickness direction,
wherein the terminal has an exposed surface exposed from the first insulating layer in the first opening, and
wherein a member between the exposed surface of the terminal and the second surface of the substrate is disposed in a state where, when light is emitted from the second surface of the substrate toward the exposed surface, the light is capable of being emitted from the first opening to the bump electrode.

13. The electronic device according to claim 12,
wherein the terminal includes a first recess formed in the exposed surface and penetrating the terminal in the thickness direction, and
wherein the bump electrode is formed so as to cover the entire first recess.

14. The electronic device according to claim 12,
wherein the terminal is made of a light-transmitting conductive material.

15. The electronic device according to claim 12,
wherein the bump electrode is formed so as to cover the entire first opening.

16. The electronic device according to claim 12,
wherein, in the plan view, the electronic device has a plurality of regions, and
wherein each of the plurality of regions includes the terminal and the bump electrode.
